(19) United States
(12) Patent Application Publication
(10) Pub. No.: US 2026/0293580 A1
(43) Pub. Date: Sep. 24, 2026

(54) PICKUP SYSTEM, BONDING DEVICE, SORTING DEVICE, AND PICKUP METHOD

(71) Applicant: PANASONIC INTELLECTUAL PROPERTY MANAGEMENT CO., LTD., Kadoma-shi, Osaka (JP)

(72) Inventors: Koji MOTOMURA, Fukuoka (JP); Masahiro KUBOTA, Fukuoka (JP); Fumio NAKAYAMA, Fukuoka (JP); Shinichi OKADA, Osaka (JP)

(21) Appl. No.: 19/475,206

(22) PCT Filed: Jul. 10, 2024
(86) PCT No.: PCT/JP2024/024890

§ 371 Date: Oct. 14, 2025

(30) Foreign Application Priority Data
Aug. 3, 2023 (JP) 2023-126976

(51) Int. Cl. H10P 72/00; H10P 72/78

(52) U.S. Cl. CPC H10P 72/0446; H10P 72/78

(57) ABSTRACT

A pickup system includes: an upward pusher that pushes a chip adhering to an adhesive sheet upward via the adhesive sheet; a component holder that includes a pickup nozzle, and holds the chip in a non-contact manner using the pickup nozzle, the pickup nozzle including an opening and being configured to be raised and lowered; a negative pressure generator that generates a negative pressure around the opening of the pickup nozzle; an ultrasonic generator that generates an ultrasonic wave by vibrating the pickup nozzle; and a controller, and the controller: causes the upward pusher to push the chip upward after causing the ultrasonic generator to generate the ultrasonic wave; and causes the negative pressure generator to generate the negative pressure in a state where the ultrasonic wave is being generated to cause the component holder to hold the chip in a non-contact manner.

### TECHNICAL FIELD

The present disclosure relates to a system which picks up components and the like.

### BACKGROUND ART

In order to achieve higher functionality in a semiconductor package, hybrid bonding which does not use bumps, bonding materials, and the like is required. In hybrid bonding, in a state where the surface of a semiconductor chip is cleaned, the semiconductor chip is bonded to a substrate or the like by utilization of hydrogen bonding or the like. Hence, in hybrid bonding, it is necessary to keep the surface of the semiconductor chip highly clean after the semiconductor chip is picked up from a dicing tape which is an adhesive sheet until the semiconductor chip is bonded.

Hence, conventionally, a manufacturing device which holds, in a non-contact manner, a semiconductor chip pushed upward by upward pushing pins has been proposed (see, for example, Patent Literature (PTL) 1). Such a manufacturing device can be said to include a pickup system which picks up the semiconductor chip as a component. The pickup system disclosed in PTL 1 holds the semiconductor chip pushed upward, in a non-contact manner, using an ultrasonic holding force and a suction force.

### CITATION LIST

### Patent Literature

[PTL 1] Japanese Unexamined Patent Application Publication No. 2023-45216

### SUMMARY OF INVENTION

### Technical Problem

Disadvantageously, however, in the pickup system disclosed in PTL 1, a bonding failure easily occurs.

For example, when a semiconductor chip is bonded to a substrate in a state where particles adhere to the semiconductor chip, the particles are sandwiched between the semiconductor chip and the substrate. This causes voids, and thus a bonding failure occurs.

Hence, the present disclosure provides a pickup system which can suppress the occurrence of a bonding failure.

### Solution to Problem

A pickup system according to an aspect of the present disclosure includes: an upward pusher that pushes a component adhering to an adhesive sheet upward via the adhesive sheet; a component holder that includes a holding tool, and holds the component in a non-contact manner using the holding tool, the holding tool including an opening and being configured to be raised and lowered; a negative pressure generator that generates a negative pressure around the opening of the holding tool; an ultrasonic generator that generates an ultrasonic wave by vibrating the holding tool; and a controller that controls the upward pusher, the component holder, the negative pressure generator, and the ultrasonic generator, and the controller: causes the upward pusher to push the component upward after causing the ultrasonic generator to generate the ultrasonic wave; and causes the negative pressure generator to generate the negative pressure in a state where the ultrasonic wave is being generated to cause the component holder to hold the component in the non-contact manner.

These general or specific aspects may be realized by a system, a method, an integrated circuit, a computer program, or a computer-readable recording medium such as a CD-ROM, or may be realized by any combination of a system, a method, an integrated circuit, a computer program, and a recording medium. The recording medium may be a non-transitory recording medium.

### Advantageous Effects of Invention

The pickup system according to the present disclosure can suppress the occurrence of a bonding failure.

Further advantages and effects in the aspect of the present disclosure will be apparent from the specification and drawings. Although such advantages and/or effects are provided by some embodiments and configurations described in the specification and drawings, not all of the configurations are necessarily required.

### BRIEF DESCRIPTION OF DRAWINGS

FIG. 1 is a perspective view of a component mounting device in an embodiment.

FIG. 2 is a diagram for illustrating an operation in which the component mounting device in the embodiment mounts a chip on a substrate.

FIG. 3 is a diagram showing an example of the configuration of a pickup system in the embodiment.

FIG. 4 is a diagram showing an example of a case where the chip to which a particle adheres is picked up.

FIG. 5A is a diagram for illustrating an example of an operation in which a pickup nozzle in the embodiment picks up the chip.

FIG. 5B is a diagram for illustrating the example of the operation in which the pickup nozzle in the embodiment picks up the chip.

FIG. 6 is a diagram showing that the magnitude of vibration of air varies depending on the position around the pickup nozzle.

FIG. 7 is a diagram showing an example of the movement of a pickup nozzle in variation 1 of the embodiment.

FIG. 8 is a diagram for illustrating static charge elimination in variation 2 of the embodiment.

FIG. 9 is a diagram for illustrating blowing of air in variation 3 of the embodiment.

FIG. 10 is a diagram for illustrating control of the downward speed of a pickup nozzle in variation 4 of the embodiment.

FIG. 11 is a diagram showing an example of the configuration of a pickup system in variation 5 of the embodiment.

FIG. 12 is a flowchart showing an example of a schematic processing operation performed by a controller in the embodiment.

### DESCRIPTION OF EMBODIMENTS

A pickup system according to a first aspect of the present disclosure includes: an upward pusher that pushes a component adhering to an adhesive sheet upward via the adhesive sheet; a component holder that includes a holding tool, and holds the component in a non-contact manner using the holding tool, the holding tool including an opening and being configured to be raised and lowered; a negative pressure generator that generates a negative pressure around the opening of the holding tool; an ultrasonic generator that generates an ultrasonic wave by vibrating the holding tool; and a controller that controls the upward pusher, the component holder, the negative pressure generator, and the ultrasonic generator, and the controller: causes the upward pusher to push the component upward after causing the ultrasonic generator to generate the ultrasonic wave; and causes the negative pressure generator to generate the negative pressure in a state where the ultrasonic wave is being generated to cause the component holder to hold the component in the non-contact manner.

In this way, the ultrasonic wave is generated in a stable state without the component being pushed upward, and thus it is possible to remove a particle adhering to the component using the ultrasonic wave. In other words, it is possible to generate the ultrasonic wave having a large sound pressure or output while suppressing tilting of the component, and to effectively remove the particle using the ultrasonic wave. Hence, when the component is held in a non-contact manner, and is bonded to the substrate or the like, the particle is prevented from being sandwiched between the component and the substrate, and thus it is possible to suppress the generation of voids, with the result that it is possible to suppress the occurrence of a bonding failure. The generation of the ultrasonic wave may be started at an arbitrary timing before the component is pushed upward. As long as the negative pressure is generated when the component is held in a non-contact manner, the generation of the negative pressure may be started at an arbitrary timing. The ultrasonic wave and the negative pressure may be constantly generated.

In a second aspect, for example, the controller: causes the upward pusher to push the component upward after causing the ultrasonic generator to generate a first ultrasonic wave as the ultrasonic wave; and causes the negative pressure generator to generate the negative pressure in a state where a second ultrasonic wave is being generated as the ultrasonic wave to cause the component holder to hold the component in a non-contact manner, the holding tool vibrates at a first vibration speed to generate the first ultrasonic wave, and the holding tool vibrates at a second vibration speed slower than the first vibration speed to generate the second ultrasonic wave. The second aspect may be dependent on the first aspect.

In this way, since the ultrasonic wave to be generated is switched from the first ultrasonic wave to the second ultrasonic wave when the component is held in a non-contact manner, that is, since the sound pressure or the output of the ultrasonic wave is lowered, it is possible to reduce the negative pressure generated by the negative pressure generator to efficiently hold the component in a non-contact manner. When the upward pusher pushes the component upward in a state where the second ultrasonic wave is being generated, it is possible to suppress the occurrence of a failure in which the component that is pushed upward to be brought into an unstable state is tilted by the ultrasonic wave having a high output. In other words, it is possible to suppress the occurrence of an error in holding the component or the occurrence of a failure in which the component is improperly held. Before the pushing upward of the component is started, the ultrasonic wave to be generated may be switched from the first ultrasonic wave to the second ultrasonic wave.

In a third aspect, the controller may cause the ultrasonic generator to gradually change a vibration speed of the holding tool from the first vibration speed to the second vibration speed. The third aspect may be dependent on the second aspect.

In this way, a rapid change in the vibration speed of the holding tool is suppressed, and thus the operation of the pickup system can be stabilized. When the sound pressure and the output of the ultrasonic wave are rapidly changed, the particle which has been once removed may adhere to the component again. However, in the third aspect, the rapid change in the sound pressure and the output of the ultrasonic wave can be suppressed, and thus the adherence of the particle on the component again can be suppressed.

In a fourth aspect, the first vibration speed may be greater than or equal to 100 mm/s and less than or equal to 3000 mm/s. The fourth aspect may be dependent on the second aspect or the third aspect.

In this way, it is possible to output the ultrasonic wave having a large sound pressure to effectively remove the particle adhering to the component.

In a fifth aspect, the second vibration speed may be greater than or equal to 10 mm/s and less than or equal to 1000 mm/s. The fifth aspect may be dependent on the second aspect or the third aspect.

In this way, for example, when the component is a silicon chip having a volume of 1 to 10mm³, the silicon chip can be appropriately held in a non-contact manner. As the size of the silicon chip is increased, the weight of the silicon chip is increased. Hence, it is necessary to increase a suction force for sucking the silicon chip by increasing the negative pressure generated by the negative pressure generator. Therefore, as the size of the silicon chip is increased, it is necessary to increase a repulsive force for moving the silicon chip away using the ultrasonic wave, with the result that the second vibration speed may be increased within the range described above.

In a sixth aspect, the controller may cause, while the ultrasonic generator is generating the ultrasonic wave, the component holder to move the holding tool alternately upward and downward. The sixth aspect may be dependent on any one of the first to fifth aspects.

In this way, even when the sound pressure of the ultrasonic wave varies depending on a distance from the holding tool, the holding tool is moved vertically, and thus it is possible to increase the possibility that a large sound pressure is applied to the component. Consequently, the particle adhering to the component can be effectively removed.

In a seventh aspect, the controller may move the holding tool by a half or more of a wavelength of the ultrasonic wave alternately upward and downward. The seventh aspect may be dependent on the sixth aspect.

In this way, it is possible to increase and decrease the sound pressure applied to the component, that is, to increase a variation range in the sound pressure, with the result that it is possible to shake the particle adhering to the component, and thus the particle can be easily removed from the component. When a standing wave is generated by the ultrasonic wave, it is possible to increase the possibility that the antinode of the standing wave can be set in the position of the particle, and thus the particle can be effectively removed.

In an eighth aspect, the pickup system further includes: a static eliminator that supplies ions to the component, and the controller may cause the static eliminator to supply ions, in the state where the ultrasonic wave is being generated, before causing the upward pusher to push the component upward. The eighth aspect may be dependent on any one of the first to seventh aspects.

In this way, since static charge elimination is performed on the component and the particle adhering to the component by ions supplied from the static eliminator, when the particle adheres to the component by static electricity, the particle can be easily removed from the component. Hence, it is possible to more effectively remove the particle.

In a ninth aspect, the pickup system further includes: a positive pressure generator that generates a positive pressure around the opening of the holding tool, and the controller may cause the positive pressure generator to generate the positive pressure around the opening of the holding tool, in the state where the ultrasonic wave is being generated, before causing the upward pusher to push the component upward. The ninth aspect may be dependent on any one of the first to eighth aspects.

In this way, air is blown to the component by the generation of the positive pressure, and thus, it is possible to effectively remove the particle adhering to the component.

In a tenth aspect, when the controller causes the positive pressure generator to stop generating the positive pressure, the controller may cause the positive pressure generator to gradually decrease the positive pressure. The tenth aspect may be dependent on the ninth aspect.

In an eleventh aspect, the controller may cause the holding tool to approach the component, in the state where the ultrasonic wave is being generated, before causing the upward pusher to push the component upward. The eleventh aspect may be dependent on any one of the first to tenth aspects.

In this way, the holding tool is brought close to the component, and thus it is possible to apply air pressure to the component. Consequently, it is possible to effectively remove the particle adhering to the component.

For example, when the generation of the positive pressure is suddenly stopped, the particle which has been once removed may adhere to the component again. However, in the eleventh aspect, the generation of the positive pressure is not suddenly stopped, and thus it is possible to suppress the adherence of the particle on the component again.

In a twelfth aspect, the pickup system may further include: an air supply device that supplies air toward the component. The twelfth aspect may be dependent on any one of the first to eleventh aspects.

In this way, it is possible to effectively remove the particle adhering to the component.

In a thirteenth aspect, the pickup system may further include: a collection box that is disposed to surround the component to collect a particle scattered by the air. The thirteenth aspect may be dependent on the twelfth aspect.

In this way, since the removed particle is collected into the particle collection box, it is possible to appropriately suppress the adherence of the particle on the component again.

In a fourteenth aspect, the collection box is annular. The fourteenth aspect may be dependent on the thirteenth aspect.

In this way, no matter in which direction the particle is scattered, the particle can be collected, with the result that it is possible to more appropriately suppress the adherence of the particle on the component again.

In a fifteenth aspect, the controller may start to lower the holding tool in the state where the ultrasonic wave is being generated by the ultrasonic generator. The fifteenth aspect may be dependent on any one of the first to fourteenth aspects.

In this way, the ultrasonic wave has already been generated after the downward movement of the holding tool, and thus it is possible to cause the holding tool to smoothly hold the component in a non-contact manner.

In a sixteenth aspect, the controller may start to lower the holding tool in a state where the negative pressure generator is generating the negative pressure. The sixteenth aspect may be dependent on any one of the first to fifteenth aspects.

In this way, the negative pressure has already been generated after the downward movement of the holding tool, and thus it is possible to cause the holding tool to smoothly hold the component in a non-contact manner.

A bonding device according to a seventeenth aspect of the present disclosure includes: the pickup system according to any one of the first to sixteenth aspects; and a bonder that bonds the component held by the component holder to a different component. The other component may be a substrate.

In this way, in the bonding device according to the seventeenth aspect, the same effects as those in any one of the first to sixteenth aspects can be achieved.

A sorting device according to an eighteenth aspect of the present disclosure includes: the pickup system according to any one of the first to sixteenth aspects, and the component is held by the pickup system. The sorting device is, for example, a semiconductor chip sorter.

In this way, in the sorting device according to the eighteenth aspect, the same effects as those in any one of the first to sixteenth aspects can be achieved.

An embodiment will be specifically described below with reference to drawings.

The embodiment described below indicates a general or specific example. Numerical values, shapes, materials, constituent elements, the arrangement and connection of the constituent elements, steps, the order of the steps, and the like shown in the following embodiment are examples, and are not intended to limit the present disclosure. Among the constituent elements in the following embodiment, constituent elements which are not recited in the independent claims indicating the highest level of concept are described as optional constituent elements. The drawings are schematic views, and are not exactly shown. In the drawings, the same constituent members are identified with the same reference signs.

### Embodiment

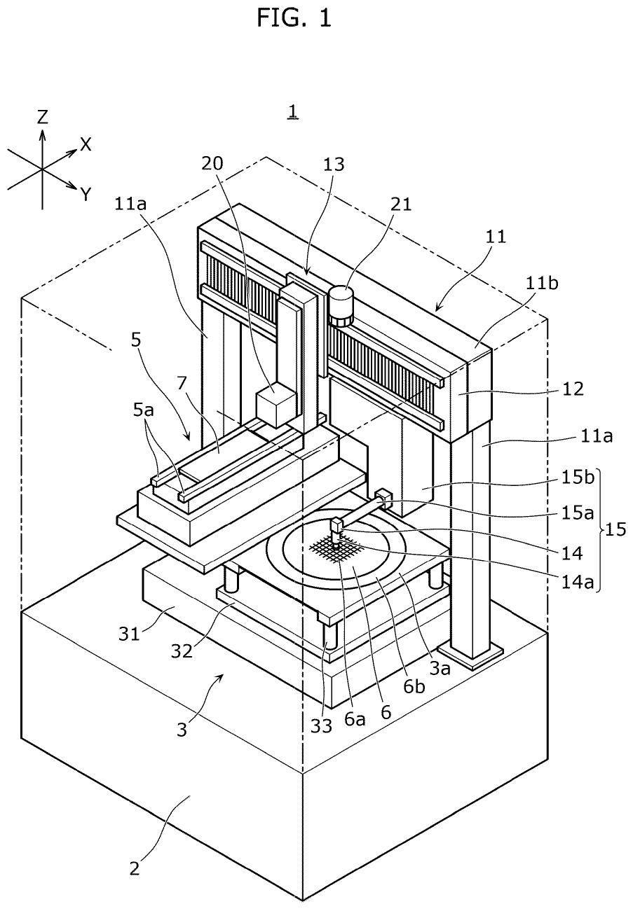

FIG. 1 is a perspective view of a component mounting device in the present embodiment.

Component mounting device 1 in the present embodiment picks up a component, and mounts the component picked up on substrate 7. Hence, component mounting device 1 in the present embodiment includes a pickup system which picks up the component. The mounting of the component on substrate 7 is also referred to as bonding of the component on substrate 7. Therefore, component mounting device 1 is also referred to as a bonding device. Substrate 7 in the present embodiment is not limited to a specific type of substrate, and may be a silicon substrate, a component, a silicon chip, or the like. In the present disclosure, a vertical direction is referred to as a Z axis direction or an up/down direction, and one direction in a plane perpendicular to the vertical direction is referred to as a Y axis direction, a left/right direction, or a lateral direction, and in the plane perpendicular thereto, a direction perpendicular to the Y axis direction is an X axis direction or a depth direction. In the present disclosure, a positive side in the Z axis direction is upward or up, and a negative side in the Z axis direction is downward or down. In the present disclosure, a positive side in the Y axis direction is a right side or right, and a negative side in the Y axis direction is a left side or left. In the present disclosure, a positive side in the X axis direction is a back side or back, and a negative side in the X axis direction is a front side or a front.

Component mounting device 1 includes base 2, component supplier 3, substrate holder 5, component holder 15, frame 11, Y axis driving mechanism 12, component mounter 13, and pickup camera 21. Base 2 is the base of component mounting device 1, and supports constituent members included in component mounting device 1.

Component supplier 3 is placed on base 2, and supplies the component to component holder 15. Component supplier 3 as described above includes holding table 3a, XY table mechanism 31, movement plate 32, and a plurality of support members 33. Holding table 3a holds semiconductor wafer unit 6 in a state where semiconductor wafer unit 6 is along a horizontal direction. Semiconductor wafer unit 6 includes adhesive sheet 6b and a plurality of chips 6a. Chips 6a are individual pieces or semiconductor chips obtained by dicing a semiconductor wafer, and are components which are supplied by component supplier 3 and mounted on substrate 7. Adhesive sheet 6b is a sheet which has adhesive properties. Chips 6a adhere to the upper surface of adhesive sheet 6b. Each of support members 33 is a columnar member which is placed on movement plate 32 so as to stand upright from movement plate 32. Support members 33 support holding table 3a in a state where semiconductor wafer unit 6 held on holding table 3a is separated upward from movement plate 32. Movement plate 32 is a plate which is disposed in XY table mechanism 31. XY table mechanism 31 moves movement plate 32 in the X axis direction and in the Y axis direction. As movement plate 32 is moved, semiconductor wafer unit 6 is moved in the X axis direction and in the Y axis direction. In other words, chips 6a are moved along an XY plane.

Pickup camera 21 is disposed above component supplier 3, and images chip 6a to be picked up in semiconductor wafer unit 6.

Substrate holder 5 holds substrate 7 in a state where substrate 7 is along the horizontal direction. Substrate holder 5 as described above includes conveyance rail 5a. Substrate holder 5 locates and holds substrate 7 conveyed by conveyance rail 5a in a mounting position. The mounting position is a position in which chip 6a is mounted.

Component holder 15 includes arm 15a, pickup head movement mechanism 15b, and pickup head 14. Arm 15a is a columnar member, and is attached to pickup head movement mechanism 15b in a state where arm 15a is along the X axis direction. In other words, one end (that is, a base end) of arm 15a in a longitudinal direction is attached to pickup head movement mechanism 15b. Pickup head 14 is attached to the other end (that is, a tip end) of arm 15a.

Pickup head movement mechanism 15b is suspended from Y axis frame 11b of frame 11, and moves arm 15a in the X axis direction, in the Y axis direction, and in the Z axis direction. Furthermore, pickup head movement mechanism 15b rotates arm 15a about a center axis along the longitudinal direction of arm 15a. In other words, pickup head movement mechanism 15b rotates arm 15a around the X axis. Pickup head 14 is attached to the tip end of arm 15a as described above. Pickup head 14 includes pickup nozzle 14a which is made of, for example, metal and holds chip 6a by vacuum suction and ultrasonic waves in a non-contact manner. Vacuum suction is the action of sucking air. Hence, pickup nozzle 14a is driven by pickup head movement mechanism 15b to move in the X axis direction, in the Y axis direction, and in the Z axis direction, and to rotate around the X axis. Pickup head movement mechanism 15b moves pickup nozzle 14a based on the result of imaging performed by pickup camera 21. In this way, pickup head movement mechanism 15b lowers pickup nozzle 14a to be able to accurately bring pickup nozzle 14a close to the upper surface of chip 6a to be picked up. Pickup nozzle 14a in the present embodiment is also simply referred to as a nozzle, and is an example of a holding tool which includes an opening for holding chip 6a by vacuum suction and ultrasonic waves in a non-contact manner.

As described above, component holder 15 in the present embodiment includes the holding tool which is pickup nozzle 14a that includes an opening, and is configured to be raised and lowered, and thereby holds chip 6a adhering to adhesive sheet 6b from above. Specifically, component holder 15 uses the holding tool to hold chip 6a in a non-contact manner. In other words, chip 6a is picked up in a non-contact manner.

Frame 11 is disposed on base 2 on the positive side in the X axis direction, and includes two support posts 11a and long Y axis frame 11b. Two support posts 11a support Y axis frame 11b in a state where Y axis frame 11b is along the Y axis direction and is separated upward from the upper surface of base 2. In other words, Y axis frame 11b is suspended by two support posts 11a. As described above, pickup head movement mechanism 15b is suspended from Y axis frame 11b.

Y axis driving mechanism 12 is attached to the surface of Y axis frame 11b on the negative side in the X axis direction, and moves component mounter 13 in the Y axis direction. Component mounter 13 includes mounting unit 20. Component mounter 13 uses mounting unit 20 to receive, from pickup nozzle 14a, chip 6a held by pickup nozzle 14a, and mounts chip 6a on substrate 7 located in the mounting position. Component mounter 13 as described above is an example of a bonder which bonds chip 6a held by component holder 15 to a different component such as substrate 7.

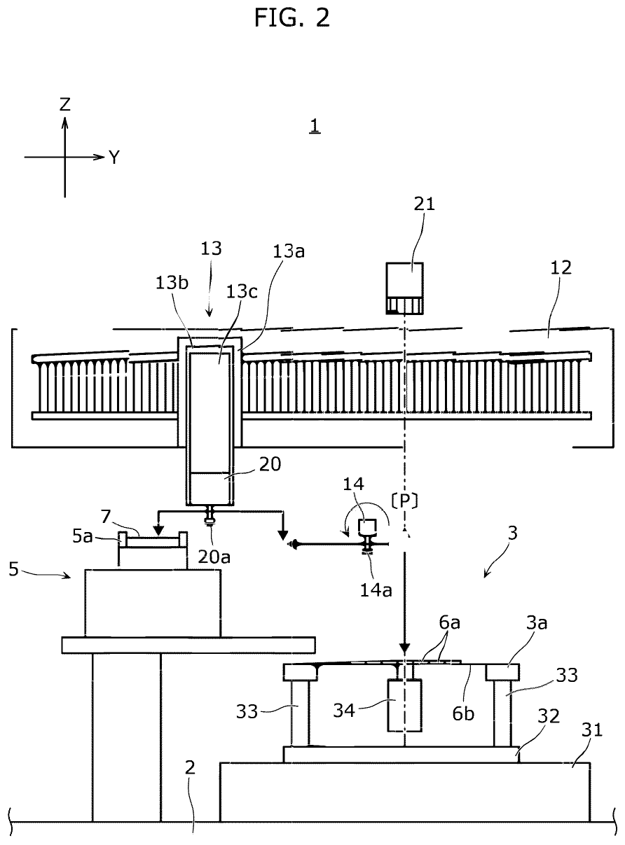

FIG. 2 is a diagram for illustrating an operation in which component mounting device 1 mounts chip 6a on substrate 7.

Component mounting device 1 picks up, among chips 6a adhering to adhesive sheet 6b, chip 6a disposed in pickup operation position P which is previously set in the XY plane, and mounts chip 6a on substrate 7.

Specifically, XY table mechanism 31 moves movement plate 32 in the X axis direction and in the Y axis direction to dispose chip 6a to be picked up in pickup operation position P. Chip 6a to be picked up which is disposed in pickup operation position P is pushed upward by upward pusher 34.

In other words, as shown in FIG. 2, component mounting device 1 in the present embodiment includes upward pusher 34 disposed in pickup operation position P. Upward pusher 34 may be included in component supplier 3. Upward pusher 34 pushes chip 6a adhering to adhesive sheet 6b upward from below via adhesive sheet 6b. Specifically, upward pusher 34 pushes upward chip 6a to be picked up which is disposed in pickup operation position P.

Pickup camera 21 is disposed above component supplier 3 and in pickup operation position P. Pickup camera 21 as described above images pickup operation position P and an area therearound from above component supplier 3 among chips 6a adhering to adhesive sheet 6b. In this way, chip 6a to be picked up is imaged, and the position of chip 6a to be picked up is recognized based on the result of the imaging. In other words, position recognition is performed on chip 6a.

Pickup nozzle 14a of pickup head 14 is driven by pickup head movement mechanism 15b to move downward, approaches, from above, chip 6a the position of which has been recognized based on the result of the imaging performed by pickup camera 21, and holds chip 6a described above. Then, pickup nozzle 14a is moved upward in a state where pickup nozzle 14a holds chip 6a, and is further moved to, for example, the negative side in the Y axis direction. Here, pickup nozzle 14a directs the lower surface (that is, the bottom surface) of chip 6a held upward by the rotation of arm 15a performed by pickup head movement mechanism 15b. In this way, chip 6a is held by pickup nozzle 14a in an upside-down state.

As shown in FIG. 2, component mounter 13 includes not only mounting unit 20 described above but also movement plate 13a, ascent/descent mechanism 13b, and ascent/descent plate 13c. Movement plate 13a is a plate which is attached to Y axis driving mechanism 12 movably in the Y axis direction. In other words, movement plate 13a is driven by Y axis driving mechanism 12 to move in the Y axis direction.

Ascent/descent mechanism 13b is attached to the front surface of movement plate 13a to cause ascent/descent plate 13c to ascend and descend. Mounting unit 20 is attached to a lower part of ascent/descent plate 13c. Mounting unit 20 includes component mounting nozzle 20a. Component mounting nozzle 20a receives chip 6a, for example, from pickup nozzle 14a which holds chip 6a in an upside-down state. For example, component mounting nozzle 20a is driven by each of Y axis driving mechanism 12 and ascent/descent mechanism 13b to move above chip 6a, and holds chip 6a, for example, by vacuum suction. Then, component mounting nozzle 20a is moved to the side of substrate 7 along the Y axis direction in a state where component mounting nozzle 20a holds chip 6a, and mounts chip 6a on substrate 7.

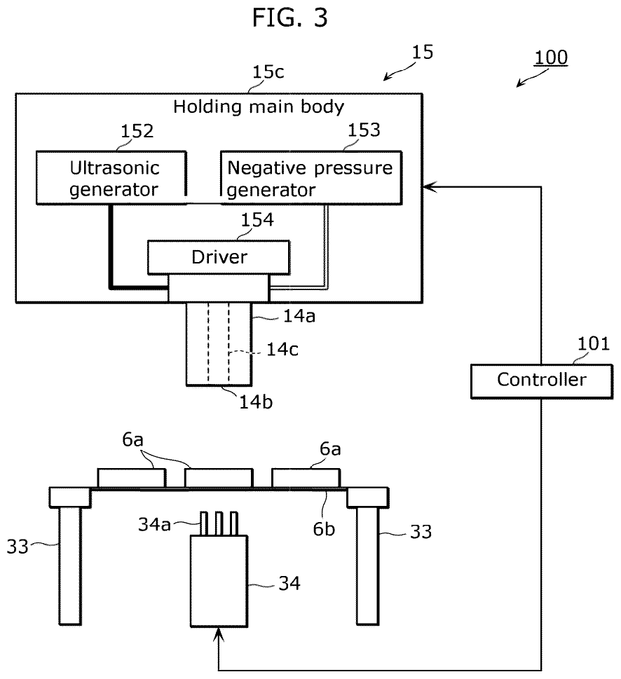

FIG. 3 is a diagram showing an example of the configuration of the pickup system in the present embodiment.

Pickup system 100 in the present embodiment is a system which is included in component mounting device 1, and includes, for example, component holder 15 described above, upward pusher 34, and controller 101.

Component holder 15 includes holding main body 15c and pickup nozzle 14a. Holding main body 15c includes, for example, arm 15a described above, pickup head movement mechanism 15b, and a part of pickup head 14 other than pickup nozzle 14a. Holding main body 15c includes ultrasonic generator 152, negative pressure generator 153, and driver 154.

Ultrasonic generator 152 vibrates (that is, ultrasonically vibrates) pickup nozzle 14a to generate ultrasonic waves from around opening 14b of pickup nozzle 14a. In other words, pickup nozzle 14a ultrasonically vibrates in the up/down direction to transmit the resulting vibrations to air in contact with the lower surface of pickup nozzle 14a. For example, ultrasonic generator 152 ultrasonically vibrates pickup nozzle 14a with an amplitude of about 10 to 20 μm at maximum.

Negative pressure generator 153 generates a negative pressure around opening 14b of pickup nozzle 14a. In the present embodiment, negative pressure generator 153 is configured, for example, as a vacuum pump. Negative pressure generator 153 as described above is a flow path formed in pickup nozzle 14a, and causes a negative pressure in flow path 14c of air communicating with opening 14b to generate the negative pressure around opening 14b. In other words, negative pressure generator 153 sucks air around opening 14b via flow path 14c to generate the negative pressure around opening 14b.

Driver 154 includes, for example, a motor or the like to move pickup nozzle 14a in the X axis direction, in the Y axis direction, and in the Z axis direction. Driver 154 rotates arm 15a to rotate pickup nozzle 14a of pickup head 14 attached to the tip end of arm 15a. Driver 154 as described above is incorporated in pickup head movement mechanism 15b.

Upward pusher 34 includes a plurality of upward pushing pins 34a, and causes upward pushing pins 34a to ascend and descend. Upward pushing pins 34a are moved upward to push up adhesive sheet 6b, and thus chip 6a adhering to adhesive sheet 6b is pushed upward.

Controller 101 controls upward pusher 34 and component holder 15. In other words, controller 101 controls upward pusher 34, ultrasonic generator 152, negative pressure generator 153, and driver 154.

Although in the present embodiment, ultrasonic generator 152 and negative pressure generator 153 are included in component holder 15, ultrasonic generator 152 and negative pressure generator 153 do not need to be included in component holder 15.

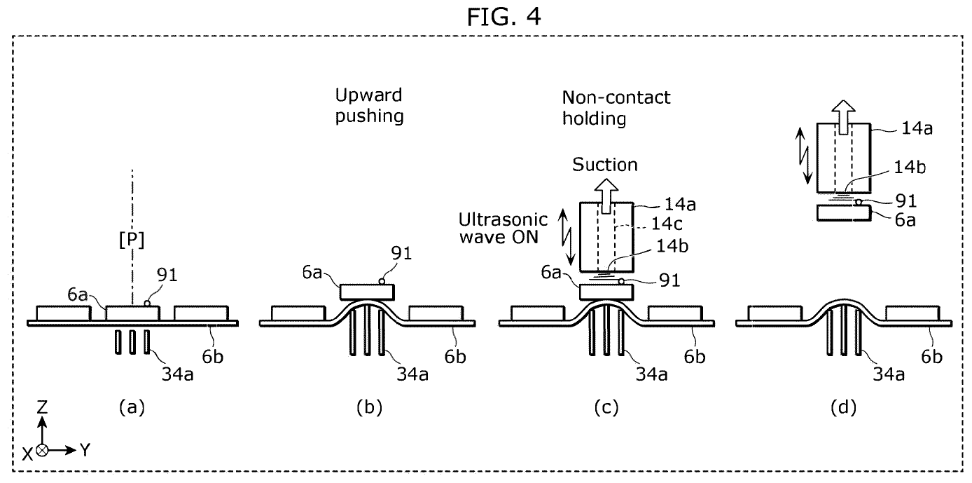

FIG. 4 is a diagram showing an example of a case where chip 6a to which a particle adheres is picked up.

For example, as shown in part (a) in FIG. 4, chip 6a to be picked up is disposed in pickup operation position P. Here, particle 91 adheres to the upper surface of chip 6a to be picked up. Then, as shown in part (b) in FIG. 4, upward pusher 34 moves upward pushing pins 34a upward to push chip 6a upward via adhesive sheet 6b. Thereafter, as shown in part (c) in FIG. 4, pickup nozzle 14a is moved downward, ultrasonic generator 152 generates ultrasonic waves, and negative pressure generator 153 generates a negative pressure. In this way, pickup nozzle 14a holds chip 6a to be picked up in a non-contact manner. Here, pickup nozzle 14a vibrates at a vibration speed of, for example, 1 to 3 mm/s, and thus the ultrasonic waves are generated by ultrasonic generator 152. Since the sound pressure of the ultrasonic waves generated at the vibration speed is small, it is highly likely that particle 91 is not removed from the upper surface of chip 6a, with the result that chip 6a may be held by pickup nozzle 14a without particle 91 being removed.

Then, as shown in part (d) in FIG. 4, pickup nozzle 14a is moved upward while holding chip 6a to which particle 91 adheres. Chip 6a held by pickup nozzle 14a as described above is mounted on substrate 7 using component mounting nozzle 20a of component mounter 13. Here, the upper surface of chip 6a is bonded to substrate 7. Hence, particle 91 adhering to the upper surface of chip 6a is sandwiched between the upper surface of chip 6a and substrate 7. In this way, voids are generated. When voids are generated, a bonding strength between chip 6a and substrate 7 is lowered. In other words, the reliability of substrate 7 on which chip 6a is mounted is lowered. Furthermore, an electrode in chip 6a cannot make contact with an electrode in substrate 7, and thus an electrical bonding failure may occur. As described above, when ultrasonic waves having a small sound pressure are used, particle 91 is not removed, and thus a bonding failure may occur.

Hence, in the present embodiment, controller 101 causes ultrasonic generator 152 to generate ultrasonic waves having a large sound pressure.

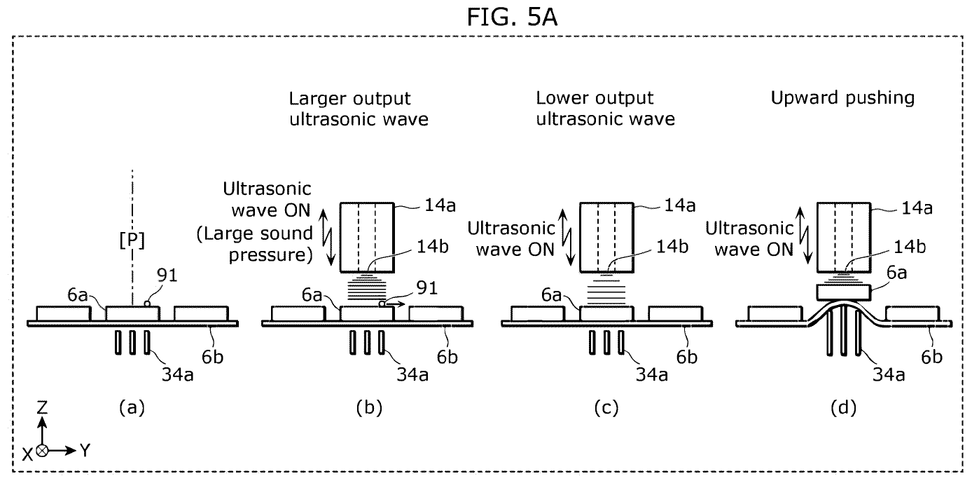

FIGS. 5A and 5B are diagrams for illustrating an example of an operation in which pickup nozzle 14a in the present embodiment picks up chip 6a.

XY table mechanism 31 first moves movement plate 32, and thus adhesive sheet 6b held by holding table 3a is moved in the X axis direction and in the Y axis direction. By the movement of adhesive sheet 6b, as shown in part (a) in FIG. 5A, chip 6a to be picked up is disposed in pickup operation position P. In other words, chip 6a to be picked up is disposed above upward pushing pins 34a of upward pusher 34. In an example shown in FIG. 5A, particle 91 adheres to the upper surface of chip 6a to be picked up. Particle 91 is a particle of a foreign substance, dust, or the like. Specifically, particle 91 is cutting waste or the like which is generated during dicing of a semiconductor wafer. More specifically, the cutting waste may adhere to a groove formed by the dicing. In such a case, when chip 6a adjacent to the groove is picked up, the cutting waste may fall on the upper surface of another chip 6a adhering to adhesive sheet 6b. Consequently, particle 91 adheres to the upper surface of another chip 6a.

Then, as shown in part (b) in FIG. 5A, controller 101 controls driver 154 to move pickup nozzle 14a downward to, for example, a height of about 50 μm from chip 6a, and causes ultrasonic generator 152 to generate ultrasonic waves. Specifically, ultrasonic generator 152 causes pickup nozzle 14a to vibrate to generate ultrasonic waves from around opening 14b of pickup nozzle 14a. Here, ultrasonic generator 152 generates, as first ultrasonic waves, ultrasonic waves having a large sound pressure or ultrasonic waves having a large output. In other words, ultrasonic generator 152 causes pickup nozzle 14a to vibrate at a first vibration speed in order to generate the first ultrasonic waves. For example, the first vibration speed is greater than or equal to 100 mm/s and less than or equal to 3000 mm/s. In this way, it is possible to output the first ultrasonic waves having a large sound pressure. Since the large sound pressure of the first ultrasonic waves is applied to chip 6a to be picked up, particle 91 adhering to chip 6a can be effectively removed from chip 6a due to the sound pressure.

Then, as shown in part (c) in FIG. 5A, controller 101 causes ultrasonic generator 152 to lower the output of ultrasonic waves. In this way, ultrasonic generator 152 generates, as second ultrasonic waves, ultrasonic waves having a small sound pressure or ultrasonic waves having a small output. In other words, ultrasonic generator 152 causes pickup nozzle 14a to vibrate at a second vibration speed in order to generate the second ultrasonic waves. The second vibration speed is slower than the first vibration speed, and is, for example, greater than or equal to 10 mm/s and less than or equal to 1000 mm/s. For example, ultrasonic generator 152 lowers the vibration speed from the first vibration speed to the second vibration speed while reducing the amplitude of the vibration without changing the frequency of the vibration of pickup nozzle 14a.

Then, as shown in part (d) in FIG. 5A, controller 101 controls upward pusher 34 to move upward pushing pins 34a upward. In this way, chip 6a is pushed upward via adhesive sheet 6b. When chip 6a is pushed upward via adhesive sheet 6b as described above, chip 6a is easily peeled off from adhesive sheet 6b. In other words, the peeling off of chip 6a from adhesive sheet 6b is facilitated. Here, pickup nozzle 14a may be moved upward in synchronization with upward pushing pins 34a. In other words, when upward pushing pins 34a are moved upward, controller 101 may control driver 154 to move pickup nozzle 14a upward such that a distance between chip 6a and pickup nozzle 14a is kept constant.

Then, as shown in part (e) in FIG. 5B, controller 101 causes negative pressure generator 153 to start the suction of air. In this way, a negative pressure is generated around opening 14b of pickup nozzle 14a. Consequently, controller 101 uses a suction force generated by the negative pressure around opening 14b and a repulsive force generated by ultrasonic waves around opening 14b, and thereby causes pickup nozzle 14a to hold chip 6a in a non-contact manner. In other words, pickup nozzle 14a uses the suction force which draws chip 6a to the side of opening 14b of pickup nozzle 14a and the repulsive force which moves chip 6a away from opening 14b, and thereby holds chip 6a in a non-contact manner. The suction force is obtained by the generation of the negative pressure performed by negative pressure generator 153. The repulsive force is obtained by the generation of the ultrasonic waves performed by ultrasonic generator 152. In the non-contact holding as described above, for example, a gap having a width of about 20 to 60 μm is generated between pickup nozzle 14a and chip 6a.

Thereafter, as shown in part (f) in FIG. 5B, controller 101 controls driver 154 to move pickup nozzle 14a upward.

As described above, in the present embodiment, controller 101 causes ultrasonic generator 152 to generate the ultrasonic waves, and thereafter causes upward pusher 34 to push chip 6a upward. Then, controller 101 causes negative pressure generator 153 to generate the negative pressure in a state where the ultrasonic waves are being generated, and causes component holder 15 to hold chip 6a in a non-contact manner.

In this way, the ultrasonic waves are generated in a stable state without chip 6a being pushed upward, and thus it is possible to remove particle 91 adhering to chip 6a using the ultrasonic waves. In other words, it is possible to generate the ultrasonic waves having a large sound pressure or output while suppressing tilting of chip 6a, and to effectively remove particle 91 using the ultrasonic waves. Hence, when chip 6a is held in a non-contact manner, and is bonded to substrate 7 with component mounting device 1, particle 91 is prevented from being sandwiched between chip 6a and substrate 7, and thus it is possible to suppress the generation of voids, with the result that it is possible to suppress the occurrence of a bonding failure.

Although in an example shown in part (b) in FIG. 5A, pickup nozzle 14a is moved downward, and thereafter ultrasonic generator 152 starts the generation of the ultrasonic waves, ultrasonic generator 152 may start the generation of the ultrasonic waves before pickup nozzle 14a is moved downward. For example, in a state where ultrasonic generator 152 generates the ultrasonic waves, controller 101 controls driver 154 to start the downward movement of pickup nozzle 14a. In this way, the ultrasonic waves have already been generated after the downward movement of pickup nozzle 14a, and thus it is possible to cause pickup nozzle 14a to smoothly hold chip 6a in a non-contact manner. In other words, ultrasonic generator 152 may start the generation of the ultrasonic waves at an arbitrary timing before chip 6a is pushed upward. Although in an example shown in FIGS. 5A and 5B, negative pressure generator 153 starts the generation of the negative pressure after chip 6a is pushed upward, negative pressure generator 153 may start the generation of the negative pressure before chip 6a is pushed upward. For example, controller 101 starts the downward movement of pickup nozzle 14a in a state where negative pressure generator 153 generates the negative pressure. In this way, the negative pressure has already been generated after the downward movement of pickup nozzle 14a, and thus it is possible to cause pickup nozzle 14a to smoothly hold chip 6a in a non-contact manner. In other words, as long as the negative pressure is generated when chip 6a is picked up, negative pressure generator 153 may start the generation of the negative pressure at an arbitrary timing. The generation of the negative pressure may be started simultaneously when chip 6a is pushed upward, or may be started simultaneously when the ultrasonic waves are generated. Alternatively, the ultrasonic waves and the negative pressure may be constantly generated. The ultrasonic waves and the negative pressure are constantly generated, and thus the generation and the stop thereof do not need to be switched, with the result that it is possible to shorten a tact time which is the time necessary to pick up and mount chip 6a.

In the present embodiment, controller 101 causes ultrasonic generator 152 to generate the first ultrasonic waves, and thereafter causes upward pusher 34 to push chip 6a upward. Then, controller 101 causes negative pressure generator 153 to generate the negative pressure in a state where ultrasonic generator 152 is caused to generate the second ultrasonic waves, and causes component holder 15 to hold chip 6a in a non-contact manner. Here, pickup nozzle 14a serving as the holding tool vibrates at the first vibration speed, and thus the first ultrasonic waves are generated, and pickup nozzle 14a vibrates at the second vibration speed slower than the first vibration speed, and thus the second ultrasonic waves are generated.

In this way, since the ultrasonic waves to be generated are switched from the first ultrasonic waves to the second ultrasonic waves when chip 6a is held in a non-contact manner, that is, since the sound pressure or the output of the ultrasonic waves is lowered, it is possible to efficiently hold chip 6a in a non-contact manner without need of a large negative pressure or suction force. When upward pusher 34 pushes chip 6a upward in a state where the second ultrasonic waves are being generated, it is possible to suppress the occurrence of a failure in which chip 6a that is pushed upward to be brought into an unstable state is tilted by the ultrasonic waves having a high output. In other words, it is possible to suppress the occurrence of an error in holding chip 6a or the occurrence of a failure in which chip 6a is improperly held.

In the present embodiment, as described above, when pickup nozzle 14a holds chip 6a in a non-contact manner, pickup nozzle 14a vibrates at the second vibration speed which is greater than or equal to 10 mm/s and less than or equal to 1000 mm/s. In this way, for example, when chip 6a is a silicon chip having a volume of 1 to 10 mm³, the silicon chip can be appropriately held in a non-contact manner. As the size of the silicon chip is increased, the weight of the silicon chip is increased. Hence, it is necessary to increase a suction force for sucking the silicon chip by increasing the negative pressure generated by negative pressure generator 153. Therefore, as the size of the silicon chip is increased, it is necessary to increase a repulsive force for moving the silicon chip away using the ultrasonic waves, with the result that the second vibration speed may be increased within the range described above.

Although in the example shown in FIGS. 5A and 5B, ultrasonic generator 152 changes the output or the sound pressure of the ultrasonic waves generated, the output or the sound pressure of the ultrasonic waves does not need to be changed. In other words, although controller 101 lowers the vibration speed of pickup nozzle 14a to switch the vibration speed from the first vibration speed to the second vibration speed, the vibration speed does not need to be lowered. For example, in a case where chip 6a is a relatively large component, even if the output of the ultrasonic waves is not lowered, it is possible to stabilize chip 6a which is pushed upward, with the result that it is possible to appropriately hold chip 6a in a non-contact manner.

Controller 101 may control ultrasonic generator 152 to gradually change the vibration speed of pickup nozzle 14a serving as the holding tool from the first vibration speed to the second vibration speed. For example, the vibration speed is changed at an acceleration of about −100 to 1000mm/s². In this way, a rapid change in the vibration speed of pickup nozzle 14a is suppressed, and thus the operation of pickup system 100 can be stabilized. When the sound pressure and the output of the ultrasonic waves are rapidly changed, particle 91 which has been once removed may adhere to chip 6a again. However, when the vibration speed is gradually changed, the rapid change in the sound pressure and the output of the ultrasonic waves can be suppressed, and thus the adherence of particle 91 on chip 6a again can be suppressed.

### Variation 1

In the present variation, controller 101 further raises and lowers pickup nozzle 14a in the state where the ultrasonic waves are being generated to remove particle 91 from chip 6a.

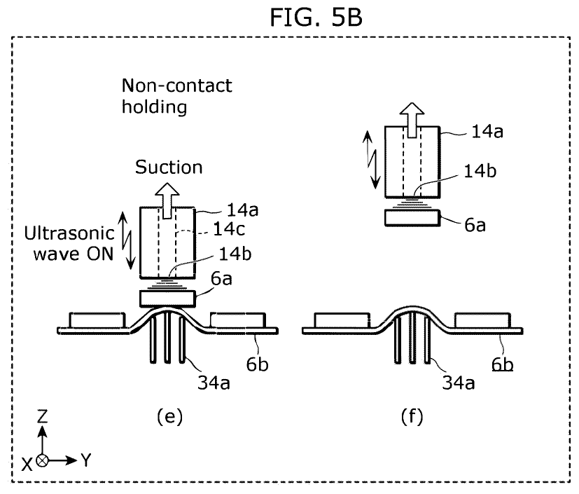

FIG. 6 is a diagram showing that the magnitude of vibration of air varies depending on the position around pickup nozzle 14a.

For example, as shown in part (a) in FIG. 6, when the ultrasonic waves are generated from several points on pickup nozzle 14a by the vibration of pickup nozzle 14a, the ultrasonic waves overlap each other, and thus position p1 where the ultrasonic waves cancel each other and position p2 where the amplitude of the ultrasonic waves is increased appear around pickup nozzle 14a.

Hence, as shown in parts (b) and (c) in FIG. 6, controller 101 in the present variation controls driver 154 in the state where the ultrasonic waves are being generated by the vibration of pickup nozzle 14a to raise and lower pickup nozzle 14a. In other words, controller 101 controls, while ultrasonic generator 152 is generating the ultrasonic waves, component holder 15 to move pickup nozzle 14a serving as the holding tool alternately upward and downward. In this way, it is possible to increase the possibility that particle 91 adhering to chip 6a is disposed in position p1 and is disposed in position p2.

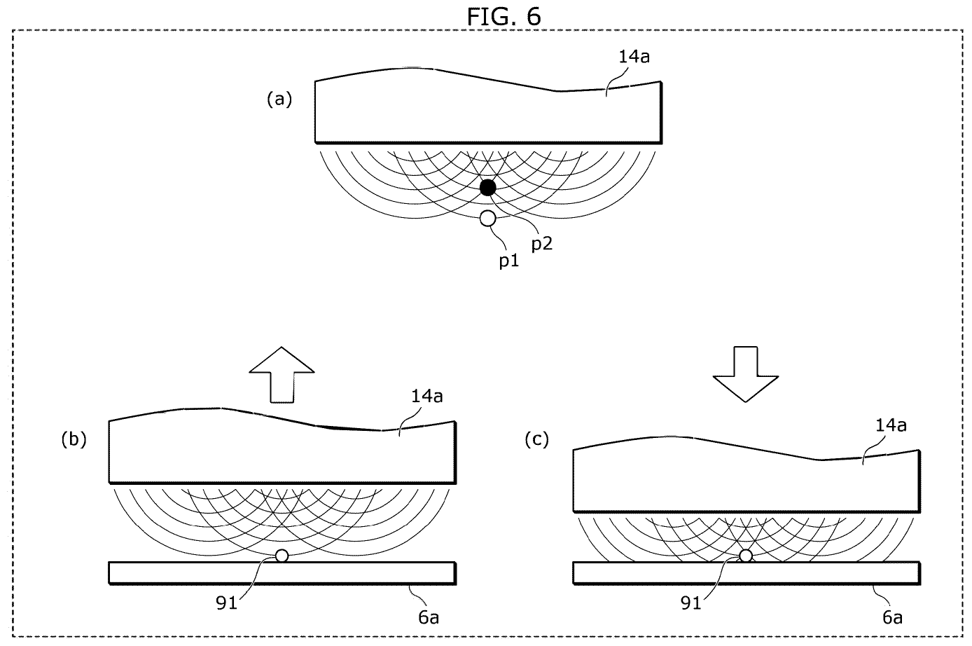

FIG. 7 is a diagram showing an example of the movement of pickup nozzle 14a in the present variation.

Controller 101 causes ultrasonic generator 152 to generate the ultrasonic waves before chip 6a is pushed upward by upward pusher 34. Then, when the ultrasonic waves are generated, for example, as shown in part (a) in FIG. 7, controller 101 controls driver 154 to lower pickup nozzle 14a. Furthermore, when the ultrasonic waves are generated, for example, as shown in part (b) in FIG. 7, controller 101 controls driver 154 to raise pickup nozzle 14a which has been lowered. The ultrasonic waves may be the first ultrasonic waves or the second ultrasonic waves.

Pickup nozzle 14a is repeatedly lowered and raised as described above. In this way, it is possible to effectively increase and decrease the sound pressure applied to particle 91 to shake particle 91, and thus particle 91 can be easily removed from chip 6a.

In other words, even when the sound pressure of the ultrasonic waves varies depending on a distance from pickup nozzle 14a, pickup nozzle 14a is moved vertically, and thus it is possible to increase the possibility that a large sound pressure is applied to chip 6a. Consequently, the particle adhering to chip 6a can be effectively removed.

In each of the upward movement shown in part (a) in FIG. 7 and the downward movement shown in part (b) in FIG. 7, controller 101 may move pickup nozzle 14a serving as the holding tool by a half or more of the wavelength of the ultrasonic waves. The ultrasonic waves are the ultrasonic waves which are generated from around opening 14b of pickup nozzle 14a by ultrasonic generator 152. When the frequency of the ultrasonic waves is 35.2 kHz, the half of the wavelength of the ultrasonic waves is, for example, about 5 mm. In this way, it is possible to effectively increase and decrease the sound pressure applied to the upper surface of chip 6a. For example, it is possible to increase the possibility that particle 91 is located at the antinode of a standing wave generated by the ultrasonic waves, and thus particle 91 adhering to chip 6a can be effectively removed.

A period during which pickup nozzle 14a is raised and lowered, that is, a period during which pickup nozzle 14a is moved upward and downward is, for example, 0.1 to 10 seconds, and the frequency thereof is 0.1 to 10 Hz. The period may be 0.5 to 2 seconds.

### Variation 2

In the present variation, controller 101 performs static charge elimination on chip 6a and particle 91 by generating ions from an ionizer.

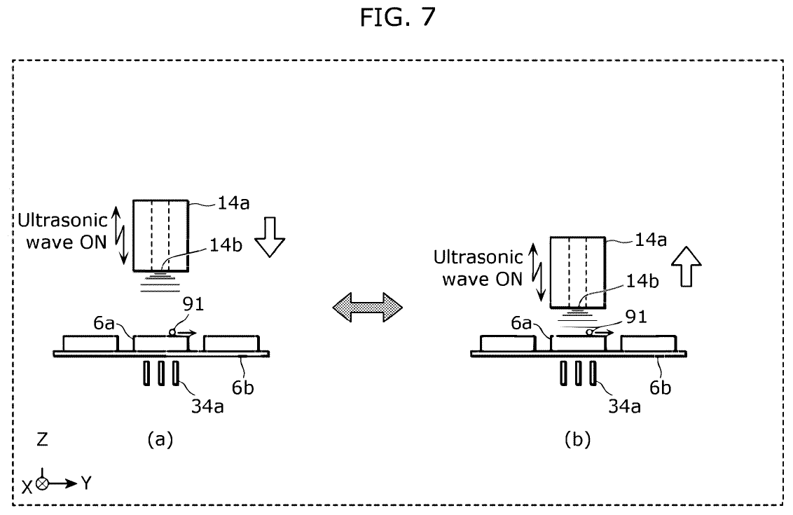

FIG. 8 is a diagram for illustrating static charge elimination in the present variation.

Pickup system 100 in the present variation includes ionizer 155. Ionizer 155 simultaneously discharges, for example, positive ions and negative ions together with air. Here, the flow rate of air is, for example, 50 to 200 L/min. In other words, pickup system 100 in the present variation includes ionizer 155 as a static eliminator for supplying ions. Controller 101 causes ionizer 155 to supply ions in the state where the ultrasonic waves are being generated before causing upward pusher 34 to push chip 6a upward. The ultrasonic waves may be the first ultrasonic waves or the second ultrasonic waves.

For example, even when the upper surface of chip 6a is negatively charged, and particle 91 is positively charged, in the present variation, the charge of chip 6a and particle 91 can be removed by ions supplied from ionizer 155. In other words, since static charge elimination is performed on chip 6a and particle 91 adhering to chip 6a by ions supplied from ionizer 155, when particle 91 adheres to chip 6a by static electricity, particle 91 can be easily removed from chip 6a. Consequently, it is possible to realize effective removal of particle 91.

### Variation 3

In the present variation, controller 101 blows air to chip 6a.

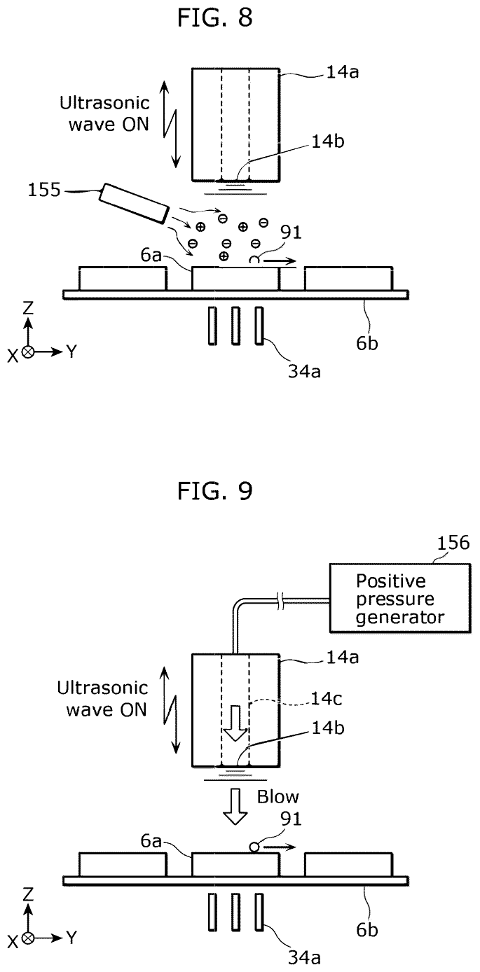

FIG. 9 is a diagram for illustrating blowing of air in the present variation.

Pickup system 100 in the present variation includes positive pressure generator 156. Positive pressure generator 156 generates a positive pressure around opening 14b of pickup nozzle 14a serving as the holding tool. For example, positive pressure generator 156 generates the positive pressure around opening 14b by changing, to the positive pressure, the pressure in flow path 14c of air which is formed in pickup nozzle 14a and communicates with opening 14b. In other words, positive pressure generator 156 blows air from opening 14b via flow path 14c. A flow path connected to negative pressure generator 153 and a flow path connected to positive pressure generator 156 may merge into flow path 14c of pickup nozzle 14a via a switching valve. In this case, by switching the flow paths with the switching valve, the generation of the negative pressure (that is, vacuum suction) and the generation of the positive pressure (that is, blowing of air) may be switched.

Then, controller 101 causes positive pressure generator 156 to generate the positive pressure around opening 14b of pickup nozzle 14a in the state where the ultrasonic waves are being generated before causing upward pusher 34 to push chip 6a upward. The ultrasonic waves may be the first ultrasonic waves or the second ultrasonic waves.

In this way, air is blown to chip 6a from pickup nozzle 14a. Consequently, it is possible to realize effective removal of particle 91 adhering to chip 6a.

When controller 101 causes positive pressure generator 156 to stop the generation of the positive pressure, controller 101 may control positive pressure generator 156 to gradually decrease the positive pressure. For example, the positive pressure is decreased at a rate of change of about 0.2 to 1.0 MPa/s. Here, when the generation of the positive pressure is suddenly stopped, particle 91 which has been once removed may adhere to chip 6a again. However, in the case described above, the generation of the positive pressure is not suddenly stopped, and thus it is possible to suppress the adherence of particle 91 on chip 6a again.

### Variation 4

In the present variation, controller 101 controls the downward speed of pickup nozzle 14a to apply air pressure to chip 6a.

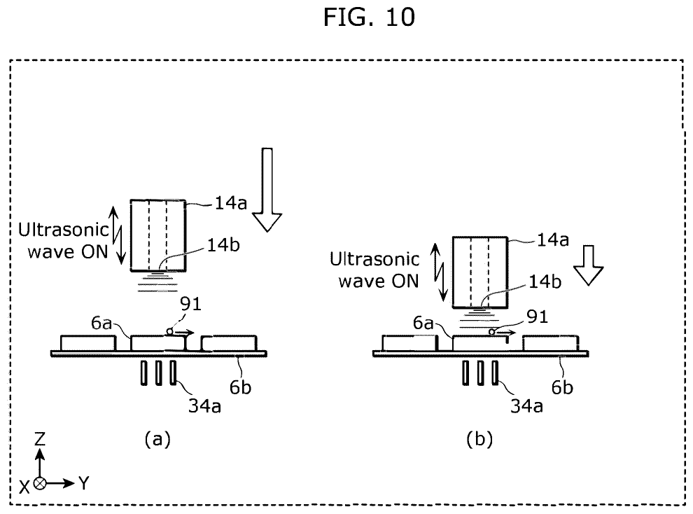

FIG. 10 is a diagram for illustrating the control of the downward speed of pickup nozzle 14a in the present variation.

Controller 101 brings pickup nozzle 14a serving as the holding tool close to chip 6a in the state where the ultrasonic waves are being generated before causing upward pusher 34 to push chip 6a upward. The ultrasonic waves may be the first ultrasonic waves or the second ultrasonic waves.

For example, as shown in part (a) in FIG. 10, pickup nozzle 14a moves downward to the vicinity of chip 6a at a first downward speed, and thereafter moves downward, as shown in part (b) in FIG. 10, to further approach chip 6a at a second downward speed slower than the first downward speed. In the downward movement at the first downward speed, pickup nozzle 14a moves downward to, for example, a position 0.5 to 2 mm above chip 6a. In the downward movement at the second downward speed, pickup nozzle 14a moves downward to, for example, a position 0.05 to 0.2 mm above chip 6a.

Here, in general, the first downward speed described above is 10 to 30 mm/s, and the second downward speed described above is 0.5 to 5 mm/s. However, the first downward speed in the present variation is faster than the normal speed, and may be, for example, greater than or equal to 50 mm/s. The second downward speed in the present variation may be faster than 5 mm/s. In other words, at least one of the first downward speed or the second downward speed may be faster than the normal downward speed described above.

In this way, pickup nozzle 14a is brought close to chip 6a, and thus it is possible to apply air pressure to chip 6a. Consequently, it is possible to realize effective removal of particle 91 adhering to chip 6a.

### Variation 5

In the present variation, air is blown to the semiconductor wafer including chip 6a before chip 6a is held.

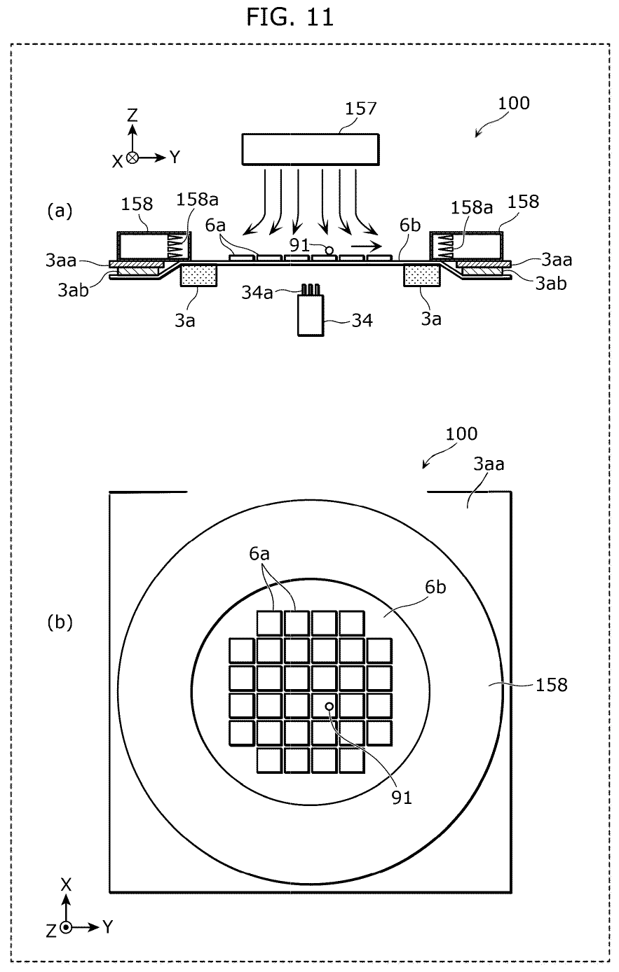

FIG. 11 is a diagram showing an example of the configuration of pickup system 100 in the present variation. Part (a) in FIG. 11 shows a state when pickup system 100 is viewed from the negative side in the X axis direction, and part (b) in FIG. 11 shows a state when pickup system 100 is viewed from the positive side in the Z axis direction.

As shown in part (a) in FIG. 11, pickup system 100 in the present variation includes air blowing device 157 and particle collection box 158. Holding table 3a in the present embodiment includes expander 3aa and wafer ring 3ab. Expander 3aa and wafer ring 3ab are jigs which expand adhesive sheet 6b in the X axis direction and in the Y axis direction to widen gaps between chips 6a included in the diced semiconductor wafer.

Air blowing device 157 is an air supply device which supplies air toward chip 6a. Specifically, as shown in part (a) in FIG. 11, air blowing device 157 is disposed above the diced semiconductor wafer (that is, chips 6a), and blows air downward according to control performed by controller 101. For example, air blowing device 157 blows air to the entire semiconductor wafer. Air blowing device 157 may be fixed above pickup nozzle 14a. Air blowing device 157 may also be configured to be movable. For example, before chip 6a is held by pickup nozzle 14a, air blowing device 157 is moved according to the control performed by controller 101 to be located above the semiconductor wafer. Then, when chip 6a is held by pickup nozzle 14a, air blowing device 157 is moved according to the control performed by controller 101 to be retracted to a place other than the area above the semiconductor wafer.

Particle collection box 158 is a collection box which is disposed to surround chip 6a to collect particle 91 scattered by the air of air blowing device 157. Specifically, as shown in part (b) in FIG. 11, for example, particle collection box 158 is disposed on expander 3aa. Particle collection box 158 as described above is, for example, annular to surround the diced semiconductor wafer in an XY plane. In the surface of particle collection box 158 on the side of the semiconductor wafer, an opening is provided, and filter 158a is attached in particle collection box 158 to cover the opening.

Hence, when the air blown from air blowing device 157 hits the upper surface of the semiconductor wafer, the air flows along the upper surface and adhesive sheet 6b, and enters particle collection box 158 via the opening and filter 158a in particle collection box 158. As described above, air blowing device 157 generates the air flow around the semiconductor wafer.

Consequently, in a case where particle 91 adheres to chip 6a included in the semiconductor wafer, when air blowing device 157 blows air, particle 91 is removed from chip 6a by the air from air blowing device 157, and is collected together with the air into particle collection box 158. Filter 158a of particle collection box 158 functions as a check valve which suppresses the discharge of collected particle 91 to the outside of particle collection box 158. Particle collection box 158 may have the function of actively sucking outside air from the opening described above.

Controller 101 in the present variation blows air to air blowing device 157 before chip 6a is held by pickup nozzle 14a. Here, controller 101 may cause particle collection box 158 to suck air. Then, after air is blown by air blowing device 157, controller 101 may cause ultrasonic generator 152 to generate the ultrasonic waves.

In this way, it is possible to effectively remove particle 91 adhering to chip 6a. Since removed particle 91 is collected into particle collection box 158, it is possible to appropriately suppress the adherence of particle 91 on chip 6a again. Since particle collection box 158 is annular, no matter in which direction particle 91 is scattered, particle 91 can be collected, with the result that it is possible to more appropriately suppress the adherence of particle 91 on chip 6a again. Air blowing device 157 may constantly blow air downward.

Although in the present variation, pickup system 100 includes air blowing device 157 and particle collection box 158, a configuration may be adopted in which pickup system 100 includes air blowing device 157 but does not include particle collection box 158. In this case, air blown by air blowing device 157 is discharged to the outside of pickup system 100 from a fan disposed in a side portion or a lower portion of pickup system 100. Then, the air discharged to the outside of pickup system 100 is collected by a collection device in a clean room where pickup system 100 is disposed. When particle 91 adheres to chip 6a, particle 91 flows with the air, and is collected by the collection device in the clean room. In such a case, pickup system 100 does not need to include particle collection box 158, and thus the configuration of pickup system 100 can be simplified. On the other hand, when pickup system 100 includes air blowing device 157 and particle collection box 158, the particle can be effectively collected regardless of a complex airflow in pickup system 100 or the clean room.

### PROCESSING FLOW

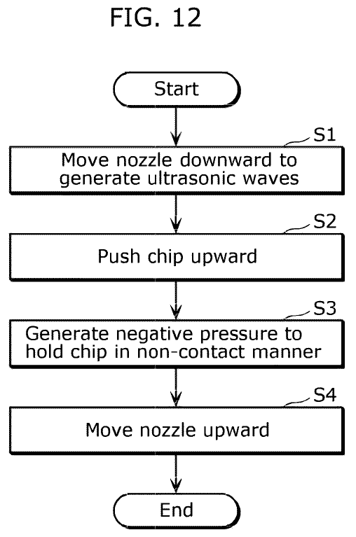

FIG. 12 is a flowchart showing an example of a schematic processing operation performed by controller 101 in the present embodiment.

Controller 101 first controls driver 154 to move pickup nozzle 14a downward, and further controls ultrasonic generator 152 to generate the ultrasonic waves from around opening 14b of pickup nozzle 14a (step S1). The ultrasonic waves generated here are ultrasonic waves which are generated at the vibration speed of pickup nozzle 14a faster than the normal vibration speed. Hence, when particle 91 adheres to chip 6a, particle 91 is removed from chip 6a by the ultrasonic waves.

Then, controller 101 controls upward pusher 34 to cause upward pusher 34 to push chip 6a upward (step S2).

Then, controller 101 controls negative pressure generator 153 to generate the negative pressure around opening 14b of pickup nozzle 14a. In this way, chip 6a is held by pickup nozzle 14a in a non-contact manner using the repulsive force formed by the ultrasonic waves and the suction force generated by the negative pressure (step S3).

Thereafter, controller 101 controls driver 154 to move pickup nozzle 14a upward (step S4).

As described above, in pickup system 100 in the present embodiment, particle 91 adhering to chip 6a can be removed, with the result that it is possible to suppress the occurrence of a bonding failure. The bonding device which is component mounting device 1 in the present embodiment includes pickup system 100 and a bonder which is component mounter 13, and bonds chip 6a held by component holder 15 to a different component. In this way, in the bonding device, the same operational effects as in pickup system 100 described above can be achieved.

Although pickup system 100 according to one or a plurality of aspects and the like have been described above based on the embodiment and the variations, the present disclosure is not limited to the embodiment and the variations. Embodiments obtained by performing various types of variations conceived by those skilled in the art on the embodiment and the variations and embodiments formed by combining the embodiment and the variations may also be included in the present disclosure as long as they do not depart from the spirit of the present disclosure.

For example, variations 1 and 2 may be combined with the embodiment described above, and variation 3 may further be combined therewith.

Although in the embodiment and the variations, chip 6a is pushed upward by upward pusher 34, chip 6a may be pushed downward. In this case, chip 6a adheres to the side of the lower surface of adhesive sheet 6b, and upward pusher 34 is disposed above adhesive sheet 6b. Upward pusher 34 pushes upward pushing pins 34a downward to push chip 6a downward via adhesive sheet 6b.

In the embodiment and the variations, the vibration speed of pickup nozzle 14a may be changed according to the size of chip 6a, the size of particle 91, and the like.

Although in the embodiment and the variations, pickup nozzle 14a holds chip 6a in a non-contact manner, component mounting nozzle 20a may hold chip 6a in a non-contact manner as with component mounting nozzle 20a.

Although in the embodiment and the variations, pickup nozzle 14a or pickup head 14 is included in component mounting device 1 which is the bonding device, pickup nozzle 14a or pickup head 14 may be included in another device. Although an example of the other device is a semiconductor chip sorter, the other device is not limited to this example. When the other device is the semiconductor chip sorter, the picking up in the embodiment and the variations means, for example, an operation of picking up a semiconductor chip from a tray or the like. Even when pickup nozzle 14a or pickup head 14 is included in the other device such as the semiconductor chip sorter, the same configuration as in the embodiment and the variations is provided, and thus a component can be appropriately held in a non-contact manner. The semiconductor chip sorter may be a sorting device which includes pickup system 100, and uses pickup system 100 to hold a semiconductor chip.

In the embodiment and the variations, controller 101 and the like may be formed by dedicated hardware, or may be realized by executing software programs suitable for controller 101. A program executor such as a central processing unit (CPU) or a processor may read and execute software programs recorded in a recording medium such as a hard disk or a semiconductor memory to realize controller 101. Here, the software which realizes controller 101 and the like causes a computer to execute, for example, the steps in the flowchart shown in FIG. 12.

The following cases are also included in the present disclosure.
(1) Specifically, controller 101 may be a computer system which includes a microprocessor, a read only memory (ROM), a random access memory (RAM), a hard disk unit, a display unit, a keyboard, a mouse, and the like. In the ROM or the hard disk unit, computer programs are stored. The microprocessor is operated according to the computer programs, and thus controller 101 achieves its functions. Here, the computer programs are formed by combining a plurality of instruction codes indicating commands to the computer in order to achieve predetermined functions.
(2) Controller 101 may be formed with one system large scale integration (LSI) circuit. The system LSI circuit is a super-multifunctional LSI circuit which is manufactured by integrating a plurality of constituent units on one chip, and is specifically a computer system which includes a microprocessor, a ROM, a RAM, and the like. In the RAM, computer programs are stored. The microprocessor is operated according to the computer programs, and thus the system LSI circuit achieves its functions.
(3) Controller 101 may be formed with a removable IC card or a single module. The IC card or the module is a computer system which includes a microprocessor, a ROM, a RAM and the like. The IC card or the module may include the super-multifunctional LSI circuit described above. The microprocessor is operated according to computer programs, and thus the IC card or the module achieves its functions. The IC card or the module may be tamper-resistant.
(4) The present disclosure may be the method described above. The present disclosure may be computer programs which realize the method using a computer, or may be digital signals of computer programs.

The present disclosure may be computer-readable recording media such as a flexible disk, a hard disk, a compact disc (CD)-ROM, a DVD, a DVD-ROM, a DVD-RAM, a Blu-ray (registered trademark) Disc (BD), and a semiconductor memory in which computer programs or digital signals are recorded. The present disclosure may be digital signals recorded in these recording media.

The present disclosure may be computer programs or digital signals which are transmitted via a telecommunication line, a wireless or wired communication line, a network such as the Internet, data broadcasting, or the like.

The present disclosure may be programs or digital signals which are recorded in a recording medium and transmitted or are transmitted via a network or the like, and are performed by a separate independent computer system.

### INDUSTRIAL APPLICABILITY

For example, the present disclosure can be utilized for a system and the like which pick up a component to perform an operation using the component.

### REFERENCE SIGNS LIST

1 component mounting device (bonding device)
2 base
3 component supplier
3a holding table
3aa expander
3ab wafer ring
5 substrate holder
5a conveyance rail
6 semiconductor wafer unit
6a chip (component)
6b adhesive sheet
7 substrate
11 frame
11a support post
11b Y axis frame
12 Y axis driving mechanism
13 component mounter
13a movement plate
13b ascent/descent mechanism
13c ascent/descent plate
14 pickup head
14a pickup nozzle (holding tool)
14b opening
14c flow path
15 component holder
15a arm
15b pickup head movement mechanism
15c holding main body
20 mounting unit
20a component mounting nozzle
21 pickup camera
31 XY table mechanism
32 movement plate
33 support member
34 upward pusher
34a upward pushing pin
91 particle
100 pickup system
101 controller
152 ultrasonic generator
153 negative pressure generator
154 driver
155 ionizer (static eliminator)
156 positive pressure generator
157 air blowing device
158 particle collection box
158a filter

What is claimed is:

1. A pickup system comprising:
an upward pusher that pushes a component adhering to an adhesive sheet upward via the adhesive sheet;
a component holder that includes a holding tool, and holds the component in a non-contact manner using the holding tool, the holding tool including an opening and being configured to be raised and lowered;
a negative pressure generator that generates a negative pressure around the opening of the holding tool;
an ultrasonic generator that generates an ultrasonic wave by vibrating the holding tool; and
a controller that controls the upward pusher, the component holder, the negative pressure generator, and the ultrasonic generator,
wherein the controller:
causes the upward pusher to push the component upward after causing the ultrasonic generator to generate the ultrasonic wave; and
causes the negative pressure generator to generate the negative pressure in a state where the ultrasonic wave is being generated to cause the component holder to hold the component in the non-contact manner.

2. The pickup system according to claim 1,
wherein the controller:
causes the upward pusher to push the component upward after causing the ultrasonic generator to generate a first ultrasonic wave as the ultrasonic wave; and
causes the negative pressure generator to generate the negative pressure in a state where a second ultrasonic wave is being generated as the ultrasonic wave to cause the component holder to hold the component in the non-contact manner,
the holding tool vibrates at a first vibration speed to generate the first ultrasonic wave, and
the holding tool vibrates at a second vibration speed slower than the first vibration speed to generate the second ultrasonic wave.

3. The pickup system according to claim 2,
wherein the controller causes the ultrasonic generator to gradually change a vibration speed of the holding tool from the first vibration speed to the second vibration speed.

4. The pickup system according to claim 2,
wherein the first vibration speed is greater than or equal to 100 mm/s and less than or equal to 3000 mm/s.

5. The pickup system according to claim 2,
wherein the second vibration speed is greater than or equal to 10 mm/s and less than or equal to 1000 mm/s.

6. The pickup system according to claim 1,
wherein the controller causes, while the ultrasonic generator is generating the ultrasonic wave, the component holder to move the holding tool alternately upward and downward.

7. The pickup system according to claim 6,
wherein the controller moves the holding tool by a half or more of a wavelength of the ultrasonic wave alternately upward and downward.

8. The pickup system according to claim 1, further comprising:
a static eliminator that supplies ions to the component,
wherein the controller causes the static eliminator to supply ions, in the state where the ultrasonic wave is being generated, before causing the upward pusher to push the component upward.

9. The pickup system according to claim 1, further comprising:
a positive pressure generator that generates a positive pressure around the opening of the holding tool,
wherein the controller causes the positive pressure generator to generate the positive pressure around the opening of the holding tool, in the state where the ultrasonic wave is being generated, before causing the upward pusher to push the component upward.

10. The pickup system according to claim 9,
wherein when the controller causes the positive pressure generator to stop generating the positive pressure, the controller causes the positive pressure generator to gradually decrease the positive pressure.

11. The pickup system according to claim 1,
wherein the controller causes the holding tool to approach the component, in the state where the ultrasonic wave is being generated, before causing the upward pusher to push the component upward.

12. The pickup system according to claim 1, further comprising:
an air supply device that supplies air toward the component.

13. The pickup system according to claim 12, further comprising:
a collection box that is disposed to surround the component to collect a particle scattered by the air.

14. The pickup system according to claim 13,
wherein the collection box is annular.

15. The pickup system according to claim 1,
wherein the controller starts to lower the holding tool in the state where the ultrasonic wave is being generated by the ultrasonic generator.

16. The pickup system according to claim 1,
wherein the controller starts to lower the holding tool in a state where the negative pressure generator is generating the negative pressure.

17. A bonding device comprising:
the pickup system according to claim 1; and
a bonder that bonds the component held by the component holder to a different component.

18. A sorting device comprising:
the pickup system according to claim 1,
wherein the component is held by the pickup system.

19. A pickup method for a pickup system including: an upward pusher that pushes a component adhering to an adhesive sheet upward via the adhesive sheet; a component holder that includes a holding tool, and holds the component in a non-contact manner using the holding tool, the holding tool including an opening and being configured to be raised and lowered; a negative pressure generator that generates a negative pressure around the opening of the holding tool; and an ultrasonic generator that generates an ultrasonic wave by vibrating the holding tool, the pickup method comprising:
causing the upward pusher to push the component upward after causing the ultrasonic generator to generate the ultrasonic wave; and
causing the negative pressure generator to generate the negative pressure in a state where the ultrasonic wave is being generated to cause the component holder to hold the component in the non-contact manner.
